(19) United States
(12) Patent Application Publication
(10) Pub. No.: US 2026/0011556 A1
(43) Pub. Date: Jan. 8, 2026

(54) PLASMA PROCESSING METHOD AND PLASMA PROCESSING APPARATUS

(71) Applicant: Tokyo Electron Limited, Tokyo (JP)

(72) Inventors: Motoki NORO, Miyagi (JP); Kota ISHIHARADA, Miyagi (JP)

(73) Assignee: Tokyo Electron Limited, Tokyo (JP)

(21) Appl. No.: 19/328,251

(22) Filed: Sep. 15, 2025

Related U.S. Application Data
(63) Continuation of application No. PCT/JP2024/009310, filed on Mar. 11, 2024.

(30) Foreign Application Priority Data
Mar. 24, 2023 (JP) 2023-048053

(51) Int. Cl. H01L 21/033; H01J 37/32

(52) U.S. Cl. CPC H01L 21/0337; H01J 37/32128; H01J 37/32449; H01L 21/0332; H01J 2237/332

(57) ABSTRACT

A plasma processing method includes: (a) providing a substrate to a substrate support; and (b) forming a deposited film on a surface of the substrate before etching an etching target film, and removing a part of the deposited film. (b) repeats a cycle including a first period in which a source RF signal is supplied to a chamber and a bias signal is supplied to the substrate support, a second period in which the source RF signal with a lower power level is supplied to the chamber and the bias signal with a higher power level is supplied to the substrate support, as compared to the first period, and a third period in which the source RF signal with a lower power level is supplied to the chamber and the bias signal with a higher power level is supplied to the substrate support, as compared to the second period.

### CROSS-REFERENCE TO RELATED APPLICATIONS

This application is a bypass continuation application of international application No. PCT/JP2024/009310 having an international filing date of Mar. 11, 2024 and designating the United States, the international application being based upon and claiming the benefit of priority from Japanese Patent Application No. 2023-048053, filed on Mar. 24, 2023, the entire contents of each are incorporated herein by reference.

### BACKGROUND

### Field

An exemplary embodiment of the present disclosure relates to a plasma processing method and a plasma processing apparatus.

### Description of Related Art

Specification of U.S. Patent Application Laid-Open No. 2019/0198338 discloses a technique of supplying a deposition gas to a photoresist to form a deposition layer.

### SUMMARY

A plasma processing method in an exemplary embodiment of the present disclosure includes (a) providing a substrate including an etching target film and a resist film on the etching target film to a substrate support in a chamber, the resist film including a pattern having an opening; and (b) before etching the etching target film, forming a deposited film on at least a part of a surface of the substrate using plasma formed from a processing gas, and removing at least a part of the deposited film, in which the (b) repeats a cycle including a first period in which a source RF signal having a first power level is supplied to the chamber and a bias signal having a second power level is supplied to the substrate support, a second period in which the source RF signal having a third power level lower than the first power level is supplied to the chamber and the bias signal having a fourth power level higher than the second power level is supplied to the substrate support, and a third period in which the source RF signal having a fifth power level lower than the third power level is supplied to the chamber and the bias signal having a sixth power level higher than the fourth power level is supplied to the substrate support.

### BRIEF DESCRIPTION OF DRAWINGS

FIG. 1 is a diagram for illustrating a configuration example of a plasma processing system.

FIG. 2 is a diagram for illustrating a configuration example of a capacitively coupled plasma processing apparatus.

FIG. 3 is a flowchart illustrating an example of a plasma processing method.

FIG. 4 is a view illustrating an example of a cross-sectional structure of a substrate W provided in step ST1.

FIG. 5 is a diagram for illustrating an example of supply of a processing gas, supply of a source RF signal, and supply of a bias RF signal in step ST2.

FIG. 6 is a view for illustrating an example of a cross-sectional structure of the substrate W in a first period S1 of step ST2.

FIG. 7 is a view for illustrating an example of a cross-sectional structure of the substrate W in a second period S2 of step ST2.

FIG. 8 is a view for illustrating an example of a cross-sectional structure of the substrate W in a third period S3 of step ST2.

FIG. 9 is a view for illustrating an example of the supply of the processing gas, the supply of the source RF signal, and the supply of the bias DC signal in step ST2.

### DETAILED DESCRIPTION

Hereinafter, each embodiment of the present disclosure will be described.

In an exemplary embodiment, a plasma processing method is provided, including (a) providing a substrate including an etching target film and a resist film on the etching target film to a substrate support in a chamber, the resist film including a pattern having an opening; and (b) before etching the etching target film, forming a deposited film on at least a part of a surface of the substrate using plasma formed from a processing gas, and removing at least a part of the deposited film, in which the (b) repeats a cycle including a first period in which a source RF signal having a first power level is supplied to the chamber and a bias signal having a second power level is supplied to the substrate support, a second period in which the source RF signal having a third power level lower than the first power level is supplied to the chamber and the bias signal having a fourth power level higher than the second power level is supplied to the substrate support, and a third period in which the source RF signal having a fifth power level lower than the third power level is supplied to the chamber and the bias signal having a sixth power level higher than the fourth power level is supplied to the substrate support.

In one exemplary embodiment, the processing gas is continuously supplied into the chamber in the first period, the second period, and the third period in the (b).

In one exemplary embodiment, the processing gas includes a deposition gas for forming the deposited film and a trim gas for removing the deposited film.

In one exemplary embodiment, the deposition gas includes a carbon-containing gas.

In one exemplary embodiment, the deposition gas includes at least one selected from the group consisting of a CO gas, a CH-based gas, a CHF-based gas, and a CF-based gas.

In one exemplary embodiment, the trim gas includes at least one selected from the group consisting of an N₂ gas, an O₂ gas, a CO₂ gas, and a CO gas.

In one exemplary embodiment, the resist film includes an extreme ultraviolet (EUV) resist film.

In one exemplary embodiment, the EUV resist film includes a metal.

In one exemplary embodiment, the metal is tin.

In one exemplary embodiment, the second power level of the bias signal is a zero power level.

In one exemplary embodiment, the fifth power level of the source RF signal is a zero power level.

In one exemplary embodiment, the third period is shorter than the first period.

In one exemplary embodiment, the cycle has a period in a range of 0.01 msec to 10 msec.

In one exemplary embodiment, the bias signal is an RF signal or a direct current voltage pulse signal.

In one exemplary embodiment, the direct current voltage pulse signal has a sequence of voltage pulses having a voltage level of a negative polarity.

In one exemplary embodiment, the chamber includes an upper electrode that is disposed above the substrate support, and the source RF signal is supplied to the upper electrode.

In one exemplary embodiment, the processing gas is a gas including a CO gas and an N₂ gas.

In one exemplary embodiment, the processing gas is a gas consisting of a CO gas and an N₂ gas.

In an exemplary embodiment, a plasma processing apparatus is provided, including: a chamber; a substrate support provided in the chamber; a plasma generator; a gas supply; and a control circuitry, in which the control circuitry is configured to execute (a) providing a substrate including an etching target film and a resist film on the etching target film to the substrate support in the chamber, the resist film including a pattern having an opening, and (b) before etching the etching target film, forming a deposited film on at least a part of a surface of the substrate using plasma formed from a processing gas, and removing at least a part of the deposited film, and the (b) is executed to repeat a cycle including a first period in which a source RF signal having a first power level is supplied to the chamber and a bias signal having a second power level is supplied to the substrate support, a second period in which the source RF signal having a third power level lower than the first power level is supplied to the chamber and the bias signal having a fourth power level higher than the second power level is supplied to the substrate support, and a third period in which the source RF signal having a fifth power level lower than the third power level is supplied to the chamber and the bias signal having a sixth power level higher than the fourth power level is supplied to the substrate support.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Plasma Processing System

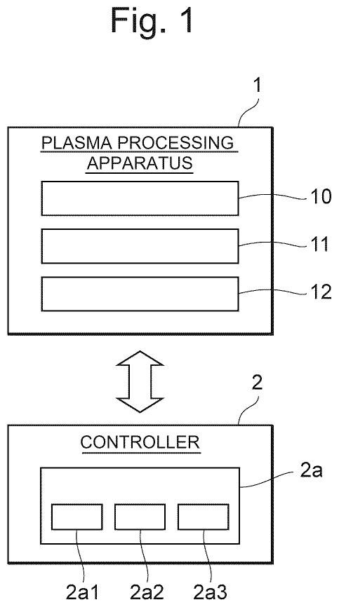

FIG. 1 is a diagram for illustrating a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20 which is described later, and the gas exhaust port is connected to an exhaust system 40 which is described later. The substrate support 11 is disposed in the plasma processing space and has a substrate support surface for supporting a substrate.

The plasma generator 12 is configured to form plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

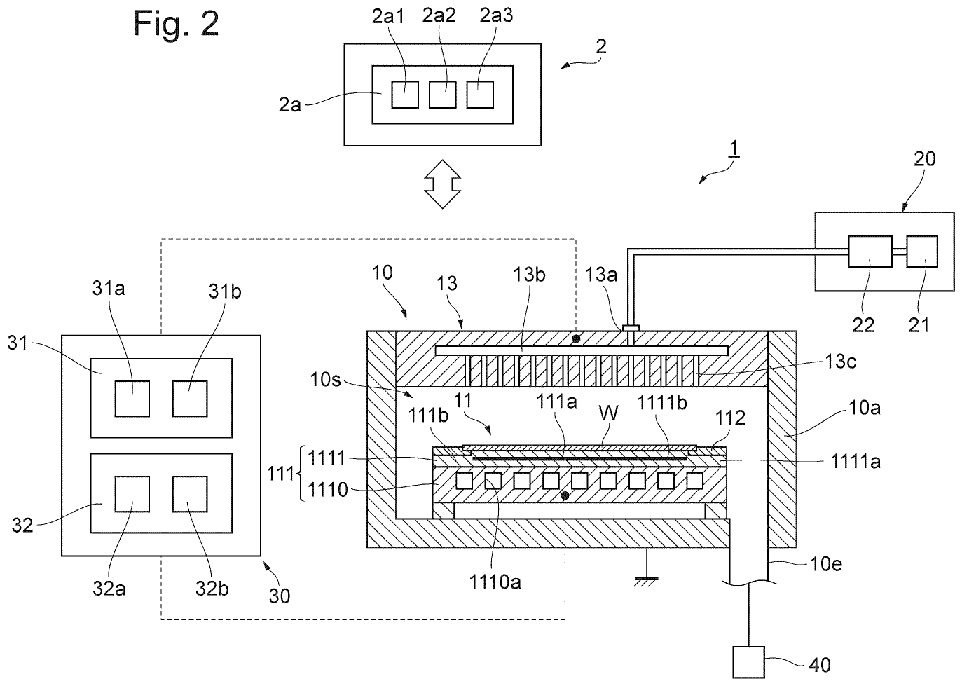

Hereinafter, a configuration example of a capacitively coupled plasma processing apparatus as an example of the plasma processing apparatus 1 will be described. FIG. 2 is a diagram for illustrating a configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or more annular members. In an embodiment, one or more of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured such that at least one processing gas is introduced from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured such that at least one RF signal (RF power) is supplied to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured such that a source RF signal (source RF power) for plasma formation is generated. In an embodiment, the source RF signal has a frequency in the range of 10 MHz to 150 MHz. In an embodiment, the first RF generator 31a may be configured such that a plurality of source RF signals having different frequencies are generated. The generated one or plurality of source RF signals is supplied to at least one lower electrode and/or at least one upper electrode.

The second RF generator 31b is coupled to at least one lower electrode via at least one impedance matching circuit and is configured such that the bias RF signal (bias RF power) is generated. The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured such that a plurality of bias RF signals having different frequencies are generated. The generated one or plurality of bias RF signals is supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and is configured such that a first DC signal is generated. The generated first DC signal is applied to at least one lower electrode. In an embodiment, the second DC generator 32b is connected to at least one upper electrode and is configured such that a second DC signal is generated. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positively-polarized voltage pulses and one or a plurality of negatively-polarized voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. A pressure in the plasma processing space 10s is regulated by the pressure regulating valve. The vacuum pump may include a turbo molecular pump, a dry pump, or a combination thereof.

### Example of Plasma Processing Method

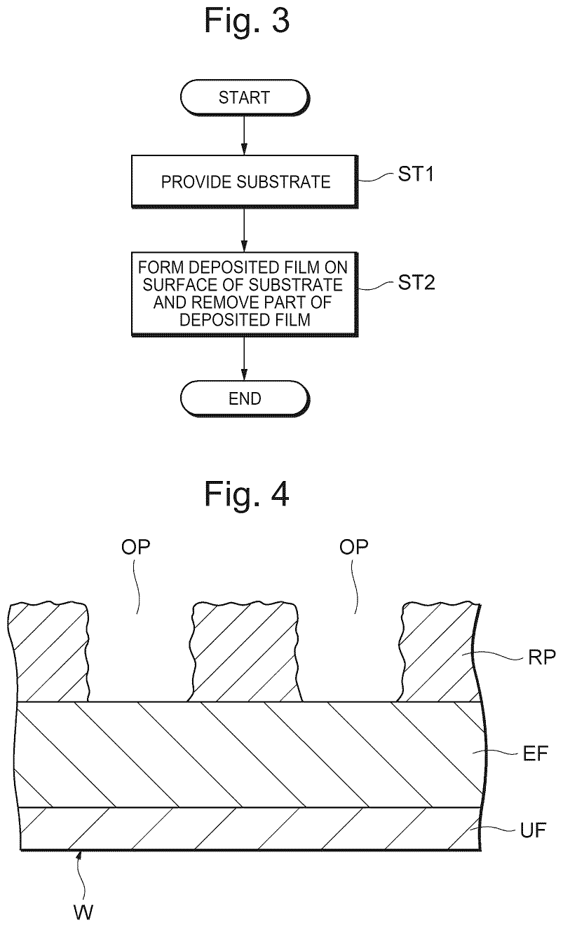

FIG. 3 is a flowchart illustrating an example of a plasma processing method (hereinafter, also referred to as “the present method”) according to one exemplary embodiment. As illustrated in FIG. 3, in an embodiment, the present method includes step ST1 of providing the substrate W, and step ST2 of forming a deposited film on a surface of the substrate W and removing a part of the deposited film. In an embodiment, the processing in each step may be performed by the plasma processing apparatus 1 (see FIG. 2). In the following example, the controller 2 controls each unit of the plasma processing apparatus 1 to execute the present method.

### (Step ST1: Providing Substrate)

In step ST1, as illustrated in FIG. 2, the substrate W may be provided in the plasma processing space 10s of the plasma processing apparatus 1. In an embodiment, the substrate W is provided in the center region 111a of the substrate support 11 and is held in the substrate support 11 by the electrostatic chuck 1111.

FIG. 4 is a view illustrating an example of a cross-sectional structure of the substrate W provided in step ST1. In an embodiment, the substrate W has an etching target film EF and a resist film (resist pattern) RP which is formed on the etching target film EF and includes a pattern. In an embodiment, an etching target film EF and a resist film RP may be formed on an underlying film UF. The substrate W may be used for manufacturing a semiconductor device. For example, the semiconductor device includes a semiconductor memory device such as a DRAM and a 3D-NAND flash memory.

In an embodiment, the underlying film UF may be a silicon wafer, an organic film, a dielectric film, a metal film, a semiconductor film, or the like formed on the silicon wafer. The underlying film UF may be configured by stacking a plurality of films.

In an embodiment, the etching target film EF is a film that is a target of etching. The etching target film EF may be, for example, an organic film, a dielectric film, a semiconductor film, or a metal film. The etching target film EF may be configured by one film or may be configured by stacking a plurality of films. For example, the etching target film EF may be configured by stacking one or a plurality of films such as a silicon-containing film, a carbon-containing film, a spin-on-glass (SOG) film, and a Si-containing antireflective coating (SiARC).

In an embodiment, the resist film RP includes a film that functions as a mask in the etching of the etching target film EF. The resist film RP may be an organic film. The resist film RP may include an extreme ultraviolet (EUV) resist film or an ArF resist film. In an example, the resist film (photoresist film) RP may be a metal-containing film. In an example, the metal-containing film is a film containing tin. In an example, the resist film RP may contain at least one of tin oxide and tin hydroxide. The tin-containing film may contain an organic substance. The resist film RP may be configured of one film, or may be configured by stacking a plurality of films. In an embodiment, as illustrated in FIG. 4, the film surface of the resist film RP of the substrate W provided in step ST1 may have unevenness. The resist film RP may have a dimension smaller than a designed dimension.

A pattern of the resist film RP may include at least one opening OP on the etching target film EF. The opening OP may be defined by a side surface of the resist film RP. The etching target film EF may be exposed on a bottom surface of the opening OP. That is, an upper surface of the etching target film EF may have a region covered with the resist film RP and a region exposed on the bottom surface of the opening OP.

The opening OP may have any shape in a plan view of the substrate W, that is, in a case where the substrate W is viewed in a direction from top to bottom in FIG. 4. The shape may be, for example, a circle, an ellipse, a rectangle, a line, or a shape in which one or more of these are combined. The resist film RP may have a plurality of side walls, and the plurality of side walls may define a plurality of openings OP. The plurality of openings OP may each have a linear shape and may be arranged at regular intervals to form a line & space pattern. In addition, the plurality of openings OP may each have a hole shape to form an array pattern.

Each of the films (the underlying film UF, the etching target film EF, and the resist film RP) constituting the substrate W may be formed by a CVD method, an ALD method, a spin coating method, or the like. The pattern of the resist film RP may be formed by lithography. The lithography may be performed using an EUV light source or an ArF light source.

In step ST1, the temperature of the substrate support 11 or the substrate W can be set to a predetermined temperature. In an embodiment, after the substrate W is provided in the center region 111a of the substrate support 11, the temperature of the substrate support 11 or the substrate W is adjusted to a set temperature by the temperature-controlled module. In an embodiment, the adjustment or maintenance of the temperature of the substrate support 11 or the substrate W includes the adjustment or maintenance of the temperature of the heat transfer fluid flowing through the flow passage 1110a to the set temperature or a temperature different from the set temperature. In an example, the adjustment or maintenance of the temperature of the substrate support 11 or the substrate W includes controlling the pressure of the heat transfer gas (for example, He) between the electrostatic chuck 1111 and the back surface of the substrate W. Timing at which the heat transfer fluid begins to flow in the flow passage 1110a may be before, after, or at the same time as the time at which the substrate W is placed on the substrate support 11. In addition, the temperature of the substrate support 11 or the substrate W may be adjusted before step ST1. That is, the substrate W may be provided on the substrate support 11 after the temperature of the substrate support 11 or the substrate W is adjusted to the set temperature.

### (Step ST2: Forming Deposited Film on Surface of Substrate and Removing Part of Deposited Film)

In step ST2, the deposited film may be formed on at least a part of the surface of the substrate W by using the plasma formed from the processing gas, and at least a part of the deposited film may be removed. In step ST2, a cycle C1 including a first period S1, a second period S2, and a third period S3 in this order is repeated a predetermined number of times.

In an embodiment, in step ST2, the processing gas is supplied into the plasma processing space 10s from the gas supply 20 illustrated in FIG. 2. In an embodiment, the source RF signal is supplied from the RF power supply 31 to the lower electrode of the substrate support 11 and/or the upper electrode of the shower head 13. As a result, a RF electric field is generated between the shower head 13 and the substrate support 11, and plasma is formed from the processing gas in the plasma processing space 10s. In an embodiment, the bias signal is supplied to the lower electrode of the substrate support 11. The bias signal may be the bias RF signal supplied from the RF power supply 31 or the bias DC signal supplied from the DC power supply 32.

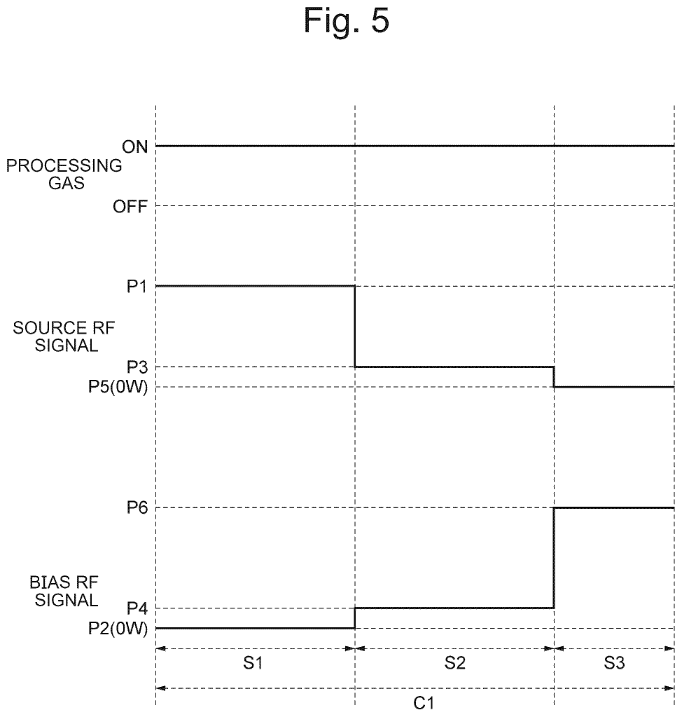

FIG. 5 is a diagram for illustrating an example of the supply of the processing gas, the supply of the source RF signal, and the supply of the bias RF signal in step ST2. As illustrated in FIG. 5, the processing gas may be continuously supplied during an entire period of the first period S1, the second period S2, and the third period S3. The processing gas may include a deposition gas for forming a deposited film and a trim gas for removing the deposited film.

The deposition gas may include a carbon-containing gas. The deposition gas may include at least one selected from the group consisting of a CO gas, a CH-based gas, a CHF-based gas, and a CF-based gas. The CH-based gas (hydrocarbon gas) may include at least one selected from the group consisting of CH₄ gas, C₂H₂ gas, C₂H₄ gas, and C₃H₆ gas. The CHF-based (hydrofluorocarbon gas) may include at least one selected from CH₂F₂ gas, CH₃F gas, and CHF₃ gas. The CF-based gas may include at least one selected from the group consisting of a CF₄ gas, a C₂F₂ gas, a C₂F₄ gas, a C₃F₆ gas, a C₃F₈ gas, a C₄F₆ gas, a C₄F₈ gas, and a C₅F₈ gas.

The trim gas may include at least one selected from the group consisting of an N₂ gas, an O₂ gas, a CO₂ gas, and a CO gas.

The processing gas may further include a rare gas such as Ar gas. The processing gas may be a gas including a CO gas and an N₂ gas. The processing gas may be a gas consisting of a CO gas and an N₂ gas.

As illustrated in FIG. 5, in the first period S1, the source RF signal having a first power level P1 may be supplied to the upper electrode of the chamber 10, and the bias RF signal having a second power level P2 may be supplied to the lower electrode of the substrate support 11. The second power level P2 may be a zero power level (OFF).

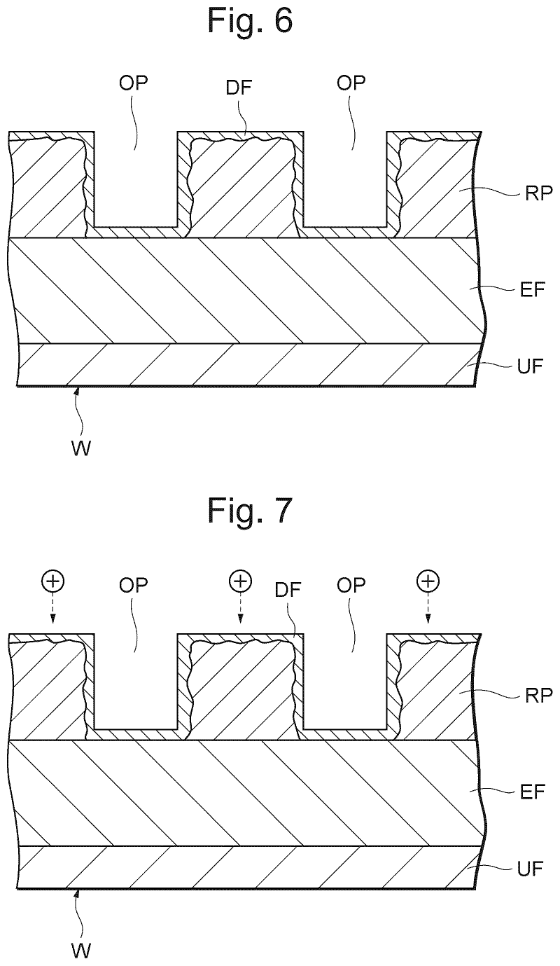

FIG. 6 is a view for illustrating an example of a cross-sectional structure of the substrate W in the first period S1. In an embodiment, as illustrated in FIG. 6, in the first period S1, ions or radicals generated from the deposition gas of the processing gas are deposited on the surface of the substrate W to form the deposited film DF. The deposited film DF may be formed on the surface of the resist film RP (the upper surface of the film and the side surface defining the opening OP) or the bottom surface of the opening OP through which the etching target film EF is exposed.

As illustrated in FIG. 5, in the second period S2, the source RF signal having a third power level P3 lower than the first power level P1 may be supplied to the upper electrode of the chamber 10, and the bias RF signal having a fourth power level P4 higher than the second power level P2 may be supplied to the lower electrode of the substrate support 11.

FIG. 7 is a view for illustrating an example of a cross-sectional structure of the substrate W in the second period S2. In an embodiment, as illustrated in FIG. 7, the ions are drawn to the surface of the substrate W, the ions react with the deposited film DF on the surface of the resist film RP, and the deposited film DF becomes carbon-rich and is cured, and the like and thereby the deposited film DF is reformed. In this case, in an embodiment, in the second period S2, the generation of ions or radicals is suppressed as compared with the first period S1, and the formation of a new deposited film DF on the surface of the resist film RP is suppressed.

As illustrated in FIG. 5, in the third period S3, the source RF signal having a fifth power level P5 lower than the third power level P3 may be supplied to the upper electrode of the chamber 10, and the bias RF signal having a sixth power level P6 higher than the fourth power level P4 may be supplied to the lower electrode of the substrate support 11. The fifth power level P5 may be the zero power level (OFF). The third period S3 may be shorter than the first period S1. The third period S3 may be shorter than the second period S2.

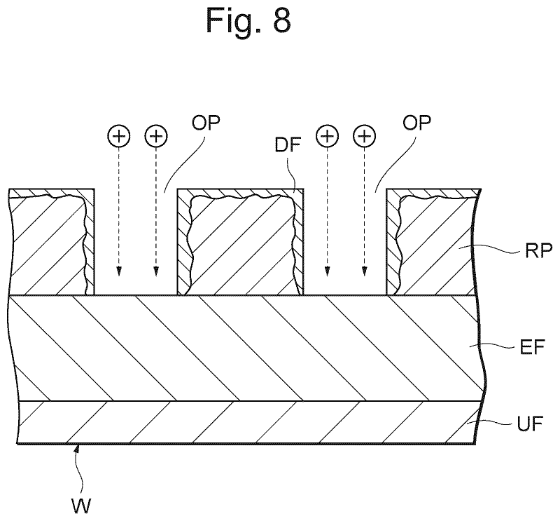

FIG. 8 is a view for illustrating an example of a cross-sectional structure of the substrate W in the third period S3. In an embodiment, as illustrated in FIG. 8, ions generated from the trim gas of the processing gas may be drawn to a substrate W side, and a part of the deposited film DF on the surface of the resist film RP may be removed. As a result, the resist film RP may be brought close to the designed dimension. In an embodiment, the deposited film DF on the bottom surface of the opening OP may be removed. As a result, a part of the surface of the etching target film EF may be exposed again to the opening OP. In an embodiment, in the third period S3, the generation of ions or radicals is suppressed as compared with the first period S1. In addition, the temperature of the ions is lowered. As a result, the ions are drawn into the opening OP perpendicularly.

The cycle C1 including the first period S1, the second period S2, and the third period S3 is repeated a predetermined number of times, and then step ST2 may be ended. The cycle C1 may be repeated 100 times or more, 150 times or more, 1,000 times or more, 5,000 times or more, 10,000 times or more, and 2,000,000 times or less. The cycle C1 may have a period in a range of 0.01 msec to 10 msec.

After the end of step ST2, subsequently, the etching target film EF may be further etched. The etching of the etching target film EF may be performed by the same plasma processing apparatus or by another plasma processing apparatus. The etching of the etching target film EF may be performed using plasma formed from the processing gas. The processing gas used for the etching of the etching target film EF may have a different gas species from the processing gas used in step ST2.

According to the present exemplary embodiment, the plasma processing method includes (a) the step (step ST1) of providing the substrate W including the etching target film EF and the resist film RP having a pattern on the etching target film EF to the substrate support 11 in the chamber 10, and (b) the step (step ST2) of forming the deposited film DF on at least a part of the surface of the substrate W using plasma formed from the processing gas before the etching target film EF is etched, and removing at least a part of the deposited film DF. The (b) step (step ST2) repeats the cycle C1 including the first period S1 in which the source RF signal having the first power level P1 is supplied to the chamber 10 and the bias signal having the second power level P2 is supplied to the substrate support 11, the second period S2 in which the source RF signal having the third power level P3 lower than the first power level P1 is supplied to the chamber 10 and the bias signal having the fourth power level P4 higher than the second power level P2 is supplied to the substrate support 11, and the third period S3 in which the source RF signal having the fifth power level P5 lower than the third power level P3 is supplied to the chamber 10 and the bias signal having the sixth power level P6 higher than the fourth power level P4 is supplied to the substrate support 11. As a result, the shape of the resist pattern can be improved. In addition, by switching the power levels of the source RF signal and the bias signal to form and remove the deposited film DF, it is possible to shorten the time required for the plasma processing for improving the shape of the resist pattern. As a result, the throughput of the plasma processing can be improved. In the second period S2, the deposited film DF formed on the surface of the resist film RP is reformed, whereby the local in-plane uniformity (LCDU) of the shape of the resist pattern can be improved. In the second period S2, the condition before the transition to the third period S3 can be adjusted. That is, by supplying the source RF signal having the third power level P3 lower than the first power level P1 in the first period S1, the plasma can be maintained, and the amount and the type of ions and radicals can be adjusted. The adjustment of the amount and the type of the ions and the radicals may include the adjustment of the dissociation amount of the trim gas. By supplying the bias signal having the fourth power level P4 higher than the second power level P2, the organic material (deposited film DF) can be altered. In this case, the carbon ratio of the deposited film DF may be increased, or the mixing of the resist film RP and the deposition gas may be promoted. As a result, the shape of the deposited film DF can be adjusted, or the deposited film DF can be promoted to adhere to the side wall of the pattern having a large line width.

Since the processing gas is continuously supplied into the chamber 10 in the first period S1, the second period S2, and the third period S3, the processing gas is not switched (ON/OFF), and as a result, the plasma processing can be performed in a short time.

Since the third period S3 is shorter than the first period S1, it is possible to suppress the damage to the film on the surface of the substrate by ions in the third period S3.

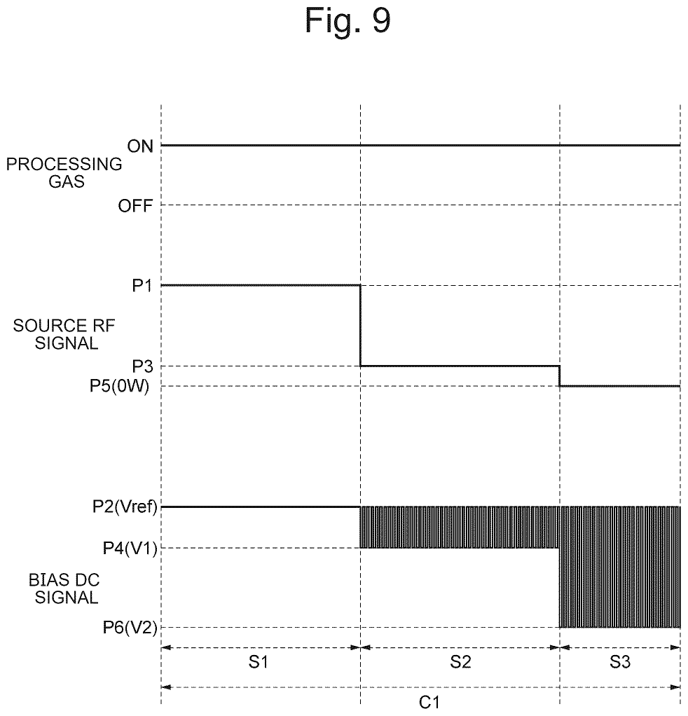

In the above-described embodiment, the bias signal supplied to the substrate support 11 may be the bias DC signal. The bias DC signal may be a direct current voltage pulse signal. The direct current voltage pulse signal may be supplied from the DC power supply 32 to the lower electrode of the substrate support 11. The direct current voltage pulse signal may have a sequence of voltage pulses having a voltage level of a negative polarity. FIG. 9 is a view for illustrating an example of the supply of the processing gas, the supply of the source RF signal, and the supply of the bias DC signal in step ST2. As illustrated in FIG. 9, the direct current voltage pulse signal, which is the bias DC signal, may have a sequence of voltage pulses in the second period S2 and the third period S3 of the cycle C1. The sequence of the voltage pulses in the second period S2 may have a voltage level V1 corresponding to the fourth power level P4, and the sequence of the voltage pulses in the third period S3 may have a voltage level V2 corresponding to the sixth power level P6. The direct current voltage pulse signal may have a reference voltage level V_{ref} corresponding to the second power level P2 in the first period S1.

In an embodiment, the reference voltage level V_{ref} may be a zero voltage level. In an embodiment, the voltage level V1 in the second period S2 and the voltage level V2 in the third period S3 may have the negative polarity. In an embodiment, an absolute value of the voltage level V2 in the third period S3 may be larger than an absolute value of the voltage level V1 in the second period S2.

In the above-described embodiment, the capacitively coupled plasma apparatus is described as an example, but the present disclosure is not limited thereto, and may be applied to other plasma apparatuses. For example, an inductively coupled plasma apparatus may be used instead of the capacitively coupled plasma apparatus.

The embodiments of the present disclosure further include the following aspects.

### Addendum 1

A plasma processing method including:
(a) providing a substrate including an etching target film and a resist film on the etching target film to a substrate support in a chamber, the resist film including a pattern having an opening; and
(b) before etching the etching target film, forming a deposited film on at least a part of a surface of the substrate using plasma formed from a processing gas, and removing at least a part of the deposited film, in which
the (b) repeats a cycle including
   a first period in which a source RF signal having a first power level is supplied to the chamber and a bias signal having a second power level is supplied to the substrate support,
   a second period in which the source RF signal having a third power level lower than the first power level is supplied to the chamber and the bias signal having a fourth power level higher than the second power level is supplied to the substrate support, and
   a third period in which the source RF signal having a fifth power level lower than the third power level is supplied to the chamber and the bias signal having a sixth power level higher than the fourth power level is supplied to the substrate support.

### Addendum 2

The plasma processing method according to Addendum 1, in which
the processing gas is continuously supplied into the chamber in the first period, the second period, and the third period in the (b).

### Addendum 3

The plasma processing method according to Addendum 1 or 2, in which
the processing gas includes a deposition gas for forming the deposited film and a trim gas for removing the deposited film.

### Addendum 4

The plasma processing method according to Addendum 3, in which
the deposition gas includes a carbon-containing gas.

### Addendum 5

The plasma processing method according to Addendum 3, in which
the deposition gas includes at least one selected from the group consisting of a CO gas, a CH-based gas, a CHF-based gas, and a CF-based gas.

### Addendum 6

The plasma processing method according to any one of Addenda 3 to 5, in which
the trim gas includes at least one selected from the group consisting of an N₂ gas, an O₂ gas, a CO₂ gas, and a CO gas.

### Addendum 7

The plasma processing method according to any one of Addenda 1 to 6, in which
the resist film includes an EUV resist film.

### Addendum 8

The plasma processing method according to Addendum 7, in which
the EUV resist film includes a metal.

### Addendum 9

The plasma processing method according to Addendum 8, in which
the metal is tin.

### Addendum 10

The plasma processing method according to any one of Addenda 1 to 9, in which
the second power level of the bias signal is a zero power level.

### Addendum 11

The plasma processing method according to any one of Addenda 1 to 10, in which
the fifth power level of the source RF signal is a zero power level.

### Addendum 12

The plasma processing method according to any one of Addenda 1 to 11, in which
the third period is shorter than the first period.

### Addendum 13

The plasma processing method according to any one of Addenda 1 to 12, in which
the cycle has a period in a range of 0.01 msec to 10 msec.

### Addendum 14

The plasma processing method according to any one of Addenda 1 to 13, in which
the bias signal is an RF signal or a direct current voltage pulse signal.

### Addendum 15

The plasma processing method according to Addendum 14, in which
the direct current voltage pulse signal has a sequence of voltage pulses having a voltage level of a negative polarity.

### Addendum 16

The plasma processing method according to any one of Addenda 1 to 15 in which
the chamber includes an upper electrode that is disposed above the substrate support, and
the source RF signal is supplied to the upper electrode.

### Addendum 17

The plasma processing method according to any one of Addenda 1 to 16, in which
the processing gas is a gas including a CO gas and an N₂ gas.

### Addendum 18

The plasma processing method according to any one of Addenda 1 to 16, in which
the processing gas is a gas consisting of a CO gas and an N₂ gas.

### Addendum 19

A plasma processing apparatus including:
a chamber;
a substrate support provided in the chamber;
a plasma generator;
a gas supply; and
a control circuitry, in which
the control circuitry is configured to execute
   (a) providing a substrate including an etching target film and a resist film on the etching target film to the substrate support in the chamber, the resist film including a pattern having an opening, and
   (b) forming a deposited film on at least a part of a surface of the substrate using plasma formed from a processing gas before etching the etching target film and removing at least a part of the deposited film, and
the (b) is executed to repeat a cycle including
   a first period in which a source RF signal having a first power level is supplied to the chamber and a bias signal having a second power level is supplied to the substrate support,
   a second period in which the source RF signal having a third power level lower than the first power level is supplied to the chamber and the bias signal having a fourth power level higher than the second power level is supplied to the substrate support, and
   a third period in which the source RF signal having a fifth power level lower than the third power level is supplied to the chamber and the bias signal having a sixth power level higher than the fourth power level is supplied to the substrate support.

Each of the above embodiments is described for the purpose of description, and it is not intended to limit the scope of the present disclosure. Each of the above embodiments may be modified in various ways without departing from the scope and gist of the present disclosure. For example, some configuration elements in one embodiment are able to be added to other embodiments. In addition, some configuration elements in one embodiment are able to be replaced with corresponding configuration elements in another embodiment. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

According to one exemplary embodiment of the present disclosure, it is possible to provide a technique for improving the shape of a resist pattern.

What is claimed is:

1. A plasma processing method comprising:
(a) providing a substrate including an etching target film and a resist film on the etching target film to a substrate support in a chamber, the resist film including a pattern having an opening; and
(b) before etching the etching target film, forming a deposited film on at least a part of a surface of the substrate using plasma formed from a processing gas, and removing at least a part of the deposited film, wherein
the (b) repeats a cycle including:
a first period in which a source RF signal having a first power level is supplied to the chamber and a bias signal having a second power level is supplied to the substrate support,
a second period in which the source RF signal having a third power level lower than the first power level is supplied to the chamber and the bias signal having a fourth power level higher than the second power level is supplied to the substrate support, and
a third period in which the source RF signal having a fifth power level lower than the third power level is supplied to the chamber and the bias signal having a sixth power level higher than the fourth power level is supplied to the substrate support.

2. The plasma processing method according to claim 1, wherein
the processing gas is continuously supplied into the chamber in the first period, the second period, and the third period in the (b).

3. The plasma processing method according to claim 1, wherein
the processing gas includes a deposition gas for forming the deposited film and a trim gas for removing the deposited film.

4. The plasma processing method according to claim 3, wherein
the deposition gas includes a carbon-containing gas.

5. The plasma processing method according to claim 3, wherein
the deposition gas includes at least one selected from the group consisting of a CO gas, a CH-based gas, a CHF-based gas, and a CF-based gas.

6. The plasma processing method according to claim 3, wherein
the trim gas includes at least one selected from the group consisting of an N₂ gas, an O₂ gas, a CO₂ gas, and a CO gas.

7. The plasma processing method according to claim 1, wherein
the resist film includes an extreme ultraviolet (EUV) resist film.

8. The plasma processing method according to claim 7, wherein
the EUV resist film includes a metal.

9. The plasma processing method according to claim 8, wherein
the metal is tin.

10. The plasma processing method according to claim 1, wherein
the second power level of the bias signal is a zero power level.

11. The plasma processing method according to claim 1, wherein
the fifth power level of the source RF signal is a zero power level.

12. The plasma processing method according to claim 1, wherein
the third period is shorter than the first period.

13. The plasma processing method according to claim 1, wherein
the cycle has a period in a range of 0.01 msec to 10 msec.

14. The plasma processing method according to claim 1, wherein
the bias signal is an RF signal or a direct current voltage pulse signal.

15. The plasma processing method according to claim 14, wherein
the direct current voltage pulse signal has a sequence of voltage pulses having a voltage level of a negative polarity.

16. The plasma processing method according to claim 1, wherein
the chamber includes an upper electrode that is disposed above the substrate support, and
the source RF signal is supplied to the upper electrode.

17. The plasma processing method according to claim 1, wherein
the processing gas includes a CO gas and an N₂ gas.

18. The plasma processing method according to claim 1, wherein
the processing gas consists of a CO gas and an N₂ gas.

19. A plasma processing apparatus comprising:
a chamber;
a substrate support provided in the chamber;
a plasma generator;
a gas supply; and
a control circuitry, wherein
the control circuitry is configured to execute
(a) providing a substrate including an etching target film and a resist film on the etching target film to the substrate support in the chamber, the resist film including a pattern having an opening, and
(b) before etching the etching target film, forming a deposited film on at least a part of a surface of the substrate using plasma formed from a processing gas, and removing at least a part of the deposited film, and
the (b) is executed to repeat a cycle including:
a first period in which a source RF signal having a first power level is supplied to the chamber and a bias signal having a second power level is supplied to the substrate support,
a second period in which the source RF signal having a third power level lower than the first power level is supplied to the chamber and the bias signal having a fourth power level higher than the second power level is supplied to the substrate support, and
a third period in which the source RF signal having a fifth power level lower than the third power level is supplied to the chamber and the bias signal having a sixth power level higher than the fourth power level is supplied to the substrate support.

20. The plasma processing apparatus according to claim 19, wherein
the processing gas is continuously supplied into the chamber in the first period, the second period, and the third period in the (b).
